(19) United States
(12) Patent Application Publication
(10) Pub. No.: US 2023/0402473 A1
(43) Pub. Date: Dec. 14, 2023

(54) MULTISPECTRAL IMAGE SENSOR AND IMAGING MODULE THEREOF

(71) Applicant: ORBBEC INC., Shenzhen (CN)

(72) Inventors: Zejia HUANG, SHENZHEN (CN); Shaoguang SHI, SHENZHEN (CN); Dingjun ZHANG, SHENZHEN (CN); Longye JIANG, SHENZHEN (CN); Wei LI, SHENZHEN (CN)

(21) Appl. No.: 18/237,241

(22) Filed: Aug. 23, 2023

Related U.S. Application Data
(63) Continuation of application No. PCT/CN2021/107954, filed on Jul. 22, 2021.

(30) Foreign Application Priority Data
Jun. 3, 2021 (CN) 202110621865.X

(51) Int. Cl. H01L 27/146

(52) U.S. Cl. CPC H01L 27/14621; H01L 27/14627; H01L 27/14645

(57) ABSTRACT

An image sensor includes a microlens array, a filter array, and a photosensitive chip sequentially arranged along a direction of incident light. The photosensitive chip includes a plurality of pixel units. The filter array includes at least one filter unit set. Each of the at least one filter unit set includes a plurality of filters corresponding to different wavelengths. Each of the plurality of filters is configured for a corresponding wavelength of the incident light to pass. The microlens array includes at least one microlens unit. The at least one microlens unit is configured to converge the incident light, and focus the converged incident light on the photosensitive chip after passing through the filter array.

### CROSS-REFERENCE TO RELATED APPLICATIONS

This application is a Continuation application of International Patent Application No. PCT/CN2021/107954 filed with the China National Intellectual Property Administration (CNIPA) on Jul. 22, 2021, which is based on and claims priority to and benefits of Chinese Patent Application No. 202110621865.X, filed on Jun. 3, 2021. The entire content of all of the above-referenced applications is incorporated herein by reference.

### TECHNICAL FIELD

This application relates to the field of data processing technologies, and in particular, to a multispectral image sensor and an imaging module.

### BACKGROUND

Spectral imaging is one of the main existing imaging technologies. Data based on spectral imaging includes both image information and spectral information. The spectral information can reflect the spectral intensity of each pixel at each wave band during the shooting of an image. A shooting object in the image may be qualitatively or even quantitatively analyzed by using the spectral information. Therefore, spectral imaging is applicable to scenarios with various different demands.

In existing technologies of multispectral image sensors, multispectral image sensors in a filter switching manner are generally used. When a multispectral image needs to be obtained, a multispectral image is acquired by switching filters corresponding to different preset wavelengths on a photosensitive chip. However, when a multispectral image sensor generated in the foregoing manner obtains a multispectral image, because different spectrums are acquired at different moments, the real-time performance is relatively low, and different spectrums are not acquired simultaneously, impacting the precision and efficiency of imaging.

### SUMMARY

The embodiments of this application provide a multispectral image sensor and an imaging module, to resolve the problem that in existing technologies of multispectral image sensors, multispectral image sensors in a filter switching manner are generally used, when a multispectral image sensor based on the principle obtains a multispectral image, because different spectrums are acquired at different moments, the real-time performance is relatively low, and different spectrums are not acquired simultaneously, resulting in relatively low precision and efficiency of imaging.

The embodiments of this application provide an image sensor, where the image sensor includes a microlens array, a filter array, and a photosensitive chip sequentially arranged in a direction of incident light, where
the photosensitive chip includes a plurality of pixel units;
the filter array includes at least one filter unit set, each of the at least one filter unit set includes a plurality of filters corresponding to different wavelengths, and each of the plurality of filters is configured for a corresponding wavelength of the incident light to pass; and
the microlens array includes at least one microlens unit, and the at least one microlens unit is configured to converge the incident light, and focus the converged incident light on the photosensitive chip after passing through the filter array.

The embodiments of this application provide an imaging device, includes at least one of the above image sensor, at least one lens, and a circuit board. The at least one image sensor and the at least one lens are arranged on the circuit board, and the at least one lens is arranged on the at least one image sensor, to irradiate the incident light on the at least one image sensor after passing through the at least one lens.

The implementation of the multispectral image sensor and the imaging module provided in the embodiments of this application has the following beneficial effects.

The multispectral image sensor provided in the embodiments of this application includes a filter array, the filter array includes at least one filter unit set, and each filter unit set includes a plurality of filters corresponding to preset wavelengths that are not identical, so that the simultaneous acquisition of optical signals in a plurality of different wave bands and the generation of multispectral image data can be implemented, thereby ensuring the real-time performance of acquisition of different channels in the multispectral image data, and providing the precision and efficiency of imaging.

### BRIEF DESCRIPTION OF THE DRAWINGS

To describe the technical solutions in the embodiments of this application more clearly, the accompanying drawings required in the description of the embodiments or existing technologies are briefly described below. Apparently, the accompanying drawings in the following description show merely some embodiments of this application, and a person of ordinary skill in the art may still derive other drawings from these accompanying drawings without creative efforts.

FIG. 1 is a schematic structural diagram of a multispectral image sensor according to an embodiment of this application.

FIG. 2 is a schematic structural diagram of a photosensitive chip 103 according to another embodiment of this application.

FIG. 3 is a schematic structural diagram between a pixel unit and a filter according to an embodiment of this application.

FIG. 4 is a schematic structural diagram between a pixel unit and a filter according to another embodiment of this application.

FIG. 5 is a schematic diagram of a filter array according to an embodiment of this application.

FIG. 6 is a schematic diagram of incident light passing through a filter unit set according to an embodiment of this application.

FIG. 7 is a schematic structural diagram of a multispectral image sensor according to another embodiment of this application.

FIG. 8 is a schematic structural diagram of an imaging module according to an embodiment of this application.

FIG. 9 is a schematic structural diagram of a multispectral image sensor according to another embodiment of this application.

FIG. 10 is a schematic diagram of a filter matrix and a filter array according to an embodiment of this application.

FIG. 11 is a schematic diagram of an RGB recovery algorithm used in a multispectral image sensor according to an embodiment of this application.

FIG. 12 is a schematic diagram of arrangement positions of different filters of RGB channels in a filter array according to an embodiment of this application.

FIG. 13 is a schematic diagram of calculation of a distortion distance according to an embodiment of this application.

FIG. 14 shows an arrangement manner of filters in a filter matrix according to another embodiment of this application.

FIG. 15 shows a parameter table of the three parameters in all candidate manners according to this application.

### DETAILED DESCRIPTION

To make the objectives, technical solutions, and advantages of this application clearer, this application is further described below in detail with reference to the accompanying drawings and embodiments. It should be understood that the specific embodiments described herein are only used for describing this application rather than limiting this application.

Data based on spectral imaging includes both image information and spectral information, and has a data type integrating an image and a spectrum. Data obtained through spectral imaging can reflect the spectral intensity of each pixel at each wave band during the shooting of an image. Qualitative and quantitative analysis, positioning analysis, and the like may be performed on an object by using spectral imaging technologies. The spectral imaging technologies may be categorized into three classes in an ascending order of the spectral resolution: multispectral imaging, high spectral imaging, and hyperspectral imaging technologies. The spectral imaging technologies have both the spectral discrimination capability and the image discrimination capability, and are applicable to the identification of geological minerals and vegetation ecology, the reconnaissance of military targets, and other scenarios.

At present, a spectral imaging device may mainly be implemented by using several solutions as follows. The first solution is a filter switching method. A multispectral image sensor based on the foregoing method includes a plurality of filters. The plurality of filters are generally located between an object under test and a lens. When image acquisition is required, the sensor switches to a specific filter based on a preset switching sequence. Only a single image with specific filtering characteristics can be outputted through a single exposure. A spectral image with multiple channels, that is, a multispectral image, is obtained by continuously switching the filters to perform a plurality of exposures. In the second solution, a push-broom method is used in the implementation of a multispectral image sensor. Only the multispectral information of the object under test in one pixel width (that is, corresponding to one column of pixels) can be outputted through a single exposure. To obtain a spatially complete two-dimensional image of the object under test, exposures need to be performed in a push-broom manner to obtain the multispectral information corresponding to a plurality of columns of pixels, to eventually synthesize a spectral image with multiple channels.

However, for the multispectral images generated in both a filter switching manner and a push-broom manner, there is a real-time performance problem. For example, for a multispectral image obtained in the filter switching manner, different spectrums have inconsistent acquisition moments, that is, there is a real-time deviation in the time domain. For a multispectral image obtained in a push-broom manner, only the multispectral information of one column of pixels can be obtained each time, and different columns have inconsistent obtaining moments, that is, there is a real-time performance deviation in the spatial domain, causing great impact on the imaging precision and efficiency of the multispectral images.

Therefore, to resolve the problem in existing technologies, this application provides a multispectral image sensor and a manufacturing method of a multispectral image sensor, to simultaneously obtain the overall multispectral information of an object under test, thereby satisfying the real-time performance of a multispectral image in the spatial domain and the time domain, and improving the imaging precision and efficiency of multispectral images.

### Embodiment 1

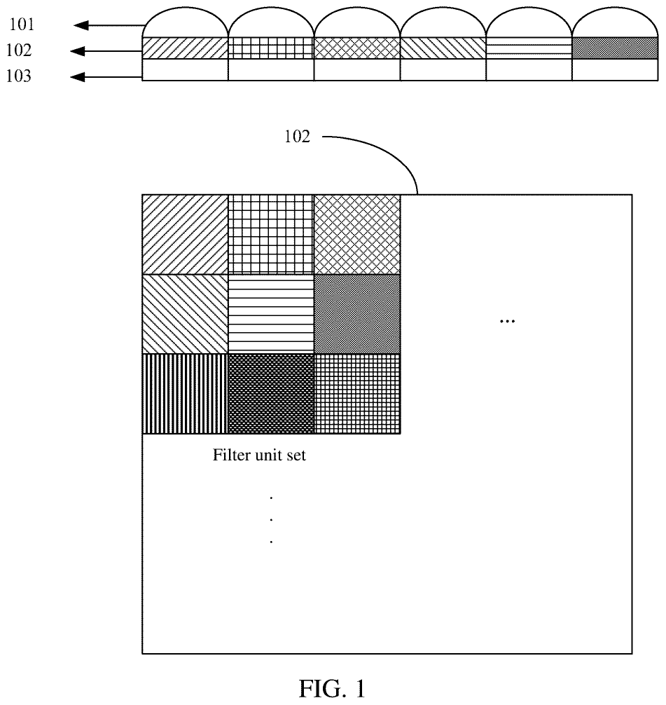

FIG. 1 is a schematic structural diagram of a multispectral image sensor according to an embodiment of this application. For ease of description, only the part related to the embodiments of this application is shown. Details are as follows.

Referring to FIG. 1, a multispectral image sensor is provided in the embodiments of this application. The multispectral image sensor includes a microlens array 101, a filter array 102, and a photosensitive chip 103 that are sequentially arranged along a direction of incident light.

The photosensitive chip 103 includes a plurality of pixel units.

The filter array 102 includes at least one filter unit set. Each filter unit set includes a plurality of filters corresponding to preset wavelengths that are not identical, that is, different wavelengths. Each filter is configured to allow the passage of light with a preset wavelength corresponding to the filter in the incident light.

The microlens array 101 includes at least one microlens unit. The microlens unit is configured to converge the incident light, and make the converged incident light pass through the filter array to focus on the photosensitive chip.

In this embodiment, the photosensitive chip 103 included in the multispectral image sensor may convert the acquired optical image information into an electrical signal, to obtain and store the image data including multiple spectrums.

In an embodiment, the photosensitive chip 103 may be a complementary metal-oxide-semiconductor (Complementary Metal-Oxide-Semiconductor, CMOS) sensor chip or may be a charge-coupled device (Charge-coupled Device, CCD) chip. Certainly, another chip that may convert an optical signal into an electrical signal may be used as the photosensitive chip 103 in this embodiment.

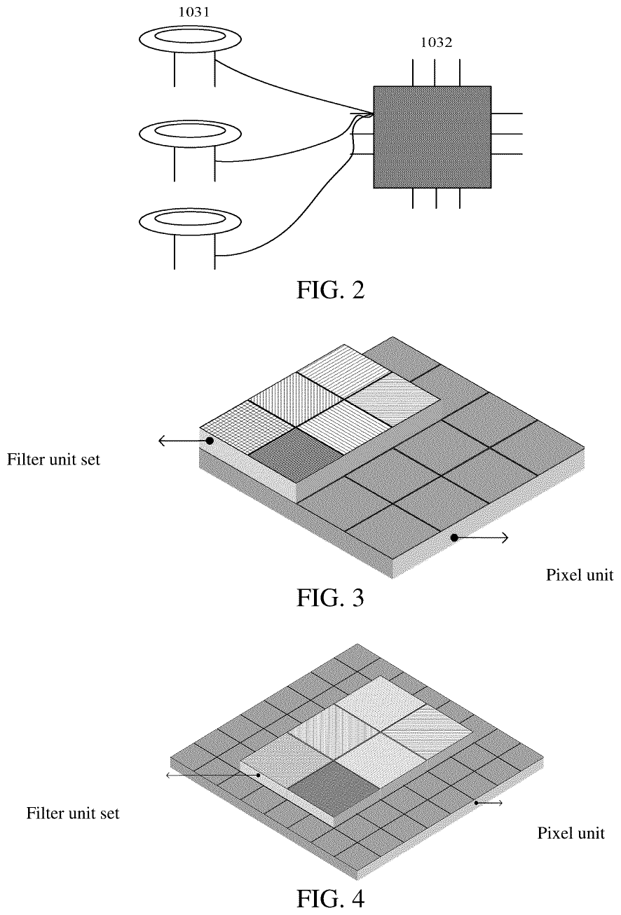

Further, FIG. 2 is a schematic structural diagram of a photosensitive chip 103 according to another embodiment of this application. Referring to FIG. 2, the photosensitive chip 103 in this embodiment may include a photodiode 1031 and a signal processing module 1032, which may also be referred to as a circuit part. The photodiode 1031 is electrically connected to the signal processing module 1032. One photosensitive chip may include a plurality of photodiodes 1031. Each pixel unit includes at least one photodiode 1031. The photodiode 1031 may convert an acquired optical signal into an electrical signal based on the photoelectric effect, and transmit the electrical signal to the signal processing module (that is, the circuit part). The signal processing module reads the electrical signal generated by the photodiode, and processes the electrical signal to obtain a corresponding light sensing result. In the multispectral image sensor, the light sensing result may also be referred to as a multispectral image. Certainly, the circuit part may further transmit the electrical signal to a connected device, for example, transmit the acquired multispectral image to a processor. In an embodiment, a layout manner of the photosensitive chip 103 may be of a front illuminated type, a back-illuminated type, a stacked type, or the like. An exposure manner of the photosensitive chip 103 may be global exposure, rolling exposure, or the like. The exposure manner and the layout manner are not limited herein.

In this embodiment, the photosensitive chip 103 includes a plurality of pixel units. Each pixel unit may acquire corresponding multispectral data. The multispectral data corresponding to the plurality of pixel units are synthesized to obtain the multispectral image data. It needs to be noted that the pixel units included in one photosensitive chip 103 may be determined according to the resolution and image size of acquisition of the pixel units, and may be correspondingly adjusted according to a use scenario. A quantity of the pixel units is not limited herein.

In an embodiment, FIG. 3 is a schematic structural diagram between a pixel unit and a filter according to an embodiment of this application. Referring to FIG. 3, one filter covers each pixel unit. In the case, an optical signal obtained by one filter through filtering is irradiated to a corresponding pixel unit. The pixel unit is configured to convert the optical signal into an electrical signal, and a multispectral image is generated based on the electrical signals of all the pixel units.

In an embodiment, FIG. 4 is a schematic structural diagram between a pixel unit and a filter according to another embodiment of this application. Referring to FIG. 4, each filter covers a plurality of pixel units. In this case, one filter covers a plurality of pixel units, so that each pixel unit may be configured to record a spectral signal of the same filter, and convert the spectral signal into a corresponding electrical signal. The foregoing structure can improve the accuracy of acquisition in a scenario with a relatively low transmittance. Although the image resolution is reduced to a certain degree, the acquisition precision of each optical signal is improved.

In this embodiment, the multispectral image sensor includes a microlens array 101. The microlens array includes at least one microlens unit, or certainly may include two or more microlens units. A specific quantity of microlens units may be correspondingly configured according to an actual scenario or a sensor requirement. The quantity of microlens units is not limited herein. The microlens array is configured to converge the incident light, and make the converged incident light pass through the filter array to focus on the photosensitive chip. The incident light may be light that is emitted by a preset light source and is reflected by an object under test or may be the light generated by the object under test.

In an embodiment, each microlens unit in the microlens array 101 corresponds to one filter unit set in a filter matrix. That is, there is a one-to-one correspondence between the microlens units and the filter unit sets. Each microlens unit is configured to converge the incident light into an area corresponding to the filter unit set, and make the incident light irradiate the photosensitive chip 103 through the filter unit set. Certainly, one microlens unit may further correspond to two or more filter unit sets. A specific correspondence manner may be determined according to an actual case.

In this embodiment, the multispectral image sensor includes a filter array 102. The filter array 102 includes at least one filter unit set. One filter unit set includes a plurality of filters. Different filters may correspond to different preset wavelengths that are not identical. That is, one filter unit set may have two or more filters corresponding to the same preset wavelength and have two or more filters corresponding to different preset wavelengths, and optical signals corresponding to different spectrums may be acquired. One filter unit set includes filters having different preset wavelengths, and different filters can only allow the passage of the light with specific wavelengths. That is, the light with a preset wavelength is obtained from the incident light through filtering. Therefore, optical signals with multiple spectrums may be obtained by using one filter unit set. After the incident light passes the through filter unit set, the photosensitive chip may acquire the optical signals with multiple spectrums, and converts the optical signals into corresponding electrical signals, thereby generating the multispectral image data.

In this embodiment, the filter array 102 of the multispectral image sensor includes a plurality of filters corresponding to different preset wavelengths. Therefore, when incident light passes through the filter array 102 to irradiate the photosensitive chip 103, the photosensitive chip may filter the light with the filter in the ranges of visible light and near infrared light (for example, light with a wave band ranging from 300 nm and 1100 nm) to obtain a multispectral image. The bandwidth of the multispectral image may range from 50 nm to 700 nm, or certainly may be greater than or less than the bandwidth ranges. An acquired multispectral image or a reconstructed multispectral image using the multispectral image sensor provided in this embodiment may be used for qualitatively analyzing components of a shooting object, for example, recognizing components of a substance, or obtaining a more precise environmental color temperature and performing color recovery on the shooting object based on the environmental color temperature, or may perform more accurate liveness detection, facial recognition, and the like. That is, the image data based on multispectral acquisition may be applied to various different use scenarios.

In an embodiment, one filter unit set may include four or more filters, for example, four filters, nine filters or sixteen filters. A specific quantity of filters is determined according to a channel quantity of the multispectral image sensor. If the filter unit set includes nine filters, the filter unit set may be a 3*3 filter matrix.

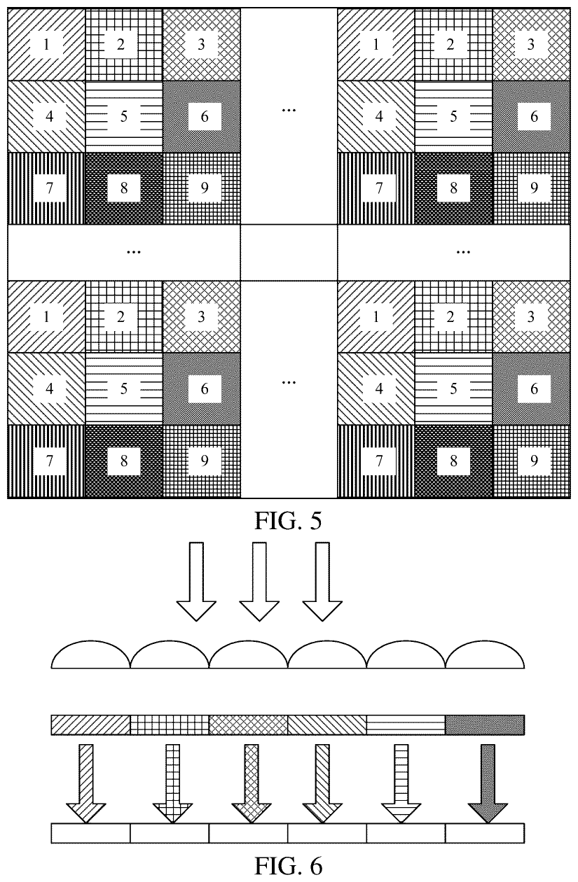

In an embodiment, for example, different filters in the same filter unit set are arranged on a two-dimensional plane in a preset arrangement manner. When a filter array includes two or more filter unit sets, because filters corresponding to different preset wavelengths in each filter unit set are arranged in the same arrangement manner, for the entire filter array, the filters corresponding to different preset wavelengths are periodically arranged in a two-dimensional plane in a preset arrangement order. For example, FIG. 5 is a schematic diagram of a filter array according to an embodiment of this application. The filter array includes four filter unit sets. Each filter unit set includes nine filters, which are filters 1 to 9 corresponding to different wavelengths. The filters in each filter unit set are arranged in the same manner, thereby forming a structure with a periodic arrangement in a preset arrangement order.

In an embodiment, for example, the filter unit set is a broadband filter matrix. Similarly, the broadband filter matrix includes a plurality of filters corresponding to different preset wavelengths. Compared with an existing multispectral image sensor, a filter unit set in the multispectral image sensor provided in the embodiments of this application may be considered as one broadband filter matrix, that is, a “broadband filter” formed by a plurality of filters corresponding to different preset wavelengths. That is, a filter unit set formed by a plurality of filters may be considered as one broadband filter. Therefore, a wave band formed by preset wavelengths corresponding to all filters included in the filter unit set may be in a relatively wide range, for example, from 300 nm to 1100 nm, or from 350 nm to 1000 nm. That is, a spectral range may be wave bands of visible light and near infrared light. A spectral transmittance curve of the broadband filter matrix may be similar to a spectral transmittance curve of a Bayer filter. The full width at half maximum (the full width at half maximum is a transmission peak width at a half of a peak height) of a transmission spectrum ranges from 50 nm to 700 nm. Different spectral transmission characteristics correspond to different colors. That is, after white light enters a filter corresponding to a preset wavelength in the broadband filter matrix, only the light with the corresponding wavelength is allowed to pass through, and the light with all the remaining wave bands is blocked. For example, FIG. 6 is a schematic diagram of incident light passing through a filter unit set according to an embodiment of this application. Referring to FIG. 6, different filters only allow the light with corresponding wave bands to pass through, and the light with other wave bands is blocked. Because one filter unit set includes filters corresponding to a plurality of different wave bands, wave bands obtained through filtering in the entire filter unit set are relatively wide, and the filter unit set may be considered as one broadband filter, that is, a broadband filter matrix.

In an embodiment, the broadband filter matrix includes a filter that may allow passage of light in a near infrared wave band, so that a spectral range in which light is allowed to pass through of the entire broadband filter matrix may be expanded. In most existing color camera modules, a filter that filters out light in a near infrared wave band (that is, does not allow the passage of light in the near infrared wave band), that is, IR-cut, is usually added to the color camera modules (between a lens and a photosensitive chip), to completely cut off light in the near infrared spectrum (650 nm to 1100 nm), to implement better color recovery. However, to expand a spectrum utilization range and obtain more spectral data to adapt to demands in different application scenarios, the multispectral image sensor provided in this application also utilizes a near infrared spectrum (when the spectrum utilization range is wider, spectral information is richer). Therefore, the multispectral image sensor may select not to use an infrared cut-off filter. That is, a filter that allows the passage of the near infrared light may be added to the broadband filter matrix, so that while color recovery can be similarly ensured, more spectral information is introduced. The filter that allows the passage of the near infrared light and a filter of another preset wave band have close response curves in the near infrared wave band. A spectral curve corresponding to each preset wavelength may be recovered by subtracting spectral information acquired by a black filter from spectral information acquired by filters corresponding to all other preset wave bands except the near infrared wave band. The filter that only responds to near infrared light is used as an IR cut filter.

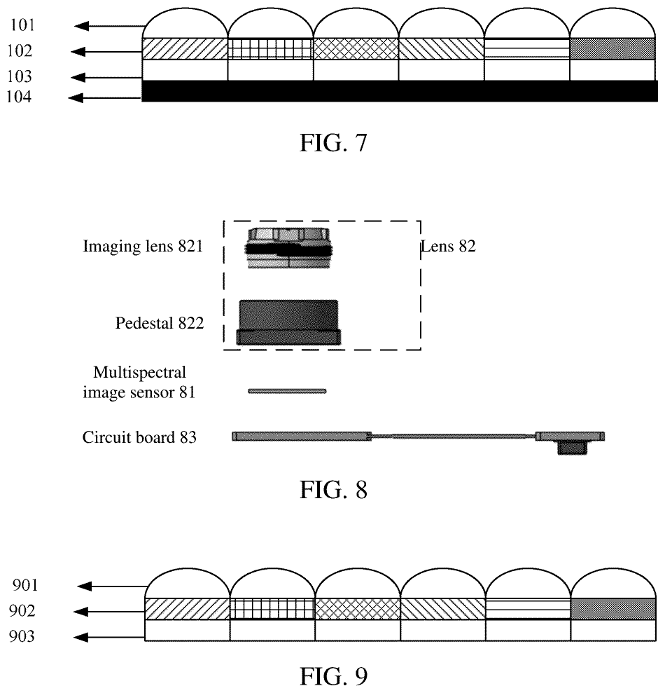

Further, in another embodiment of this application, the multispectral image sensor further includes a base 104. The photosensitive chip 103, the filter array 102, and the microlens unit 101 are sequentially arranged on the base. For example, FIG. 7 is a schematic structural diagram of a multispectral image sensor according to another embodiment of this application. Referring to FIG. 7, the multispectral image sensor includes the base 104. The photosensitive chip 103 is arranged above the base 104. The filter array 102 and the microlens unit 101 are located above the photosensitive chip 103, so that the incident light may pass through the microlens unit 101 to converge on the filter array 102, and the incident light is filtered by the filter array 102, to enable the light with multiple spectrums to irradiate the photosensitive chip 103, thereby acquiring the image data with multiple spectrums.

Further, in another embodiment of this application, this application further provides an imaging module based on the foregoing multispectral image sensor. The imaging module includes the multispectral image sensor provided in any foregoing embodiment. In addition to the foregoing multispectral image sensor, the imaging module further includes a lens and a circuit board. For example, FIG. 8 is a schematic structural diagram of an imaging module according to an embodiment of this application. Referring to FIG. 8, the imaging module includes a multispectral image sensor 81, a lens 82, and a circuit board 83. The multispectral image sensor 81 is arranged on the circuit board 83. The lens 82 is arranged above the multispectral image sensor 81 and is fixed on the circuit board 83, so that the incident light may pass through the lens to irradiate the multispectral image sensor 81. It needs to be noted that the imaging module may include one multispectral image sensor 81, or two or more multispectral image sensors 83 may be arranged. If the imaging module includes a plurality of multispectral image sensors 81, the lens 82 may be arranged above the plurality of multispectral image sensors 81. That is, the plurality of multispectral image sensors 81 correspond to one lens 82. Certainly, one independent lens 82 may be configured for every multispectral image sensor 81. A specific configuration may be configured according to an actual use scenario. This is not limited herein.

In an embodiment, the lens 82 in the imaging module includes an imaging lens 821 and a pedestal 822. The imaging lens 821 is arranged on the pedestal 822. The multispectral image sensor 81 connected to the pedestal 822 is arranged on the circuit board 83. That is, after the actual installation, the pedestal 822 covers the multispectral image sensor 81, that is, covers the entire multispectral image sensor 81 and is arranged on the circuit board 83.

In the embodiments of this application, the multispectral image sensor includes a filter array, the filter array includes at least one filter unit set, and each filter unit set includes filters corresponding to different preset wavelengths, so that the simultaneous acquisition of optical signals in a plurality of different wave bands and the generation of multispectral image data can be implemented, thereby ensuring the real-time performance of the acquisition of different channels in the multispectral image data, and providing the precision and efficiency of imaging.

### Embodiment 2

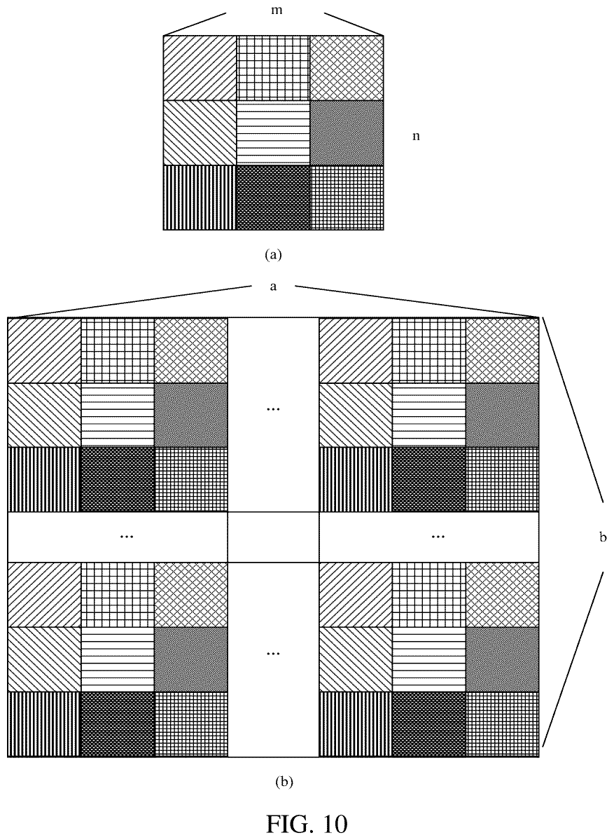

FIG. 9 is a schematic structural diagram of a multispectral image sensor according to another embodiment of this application. For ease of description, only the part related to the embodiments of this application is shown. Details are as follows.

The multispectral image sensor includes a microlens array 901, a filter array 902, and a photosensitive chip 903 that are sequentially arranged along a direction of incident light.

The photosensitive chip 903 includes a plurality of pixel units.

The filter array 902 includes at least one filter unit set. Each filter unit set includes a plurality of filters corresponding to different preset wavelengths that are not identical. Each filter is configured to allow the passage of light with a preset wavelength corresponding to the filter in the incident light. The filters in each filter unit set are arranged in a target manner. The target manner is an arrangement manner corresponding to optimal image acquisition indicators corresponding to the filter unit set.

The microlens array 901 includes at least one microlens unit. The microlens unit is configured to converge the incident light, and make the converged incident light pass through the filter array to focus on the photosensitive chip.

In this embodiment, the photosensitive chip 903 and the microlens array 901 are respectively the same as the photosensitive chip 103 and the microlens array 101 in Embodiment 1, and are both configured to convert an optical signal into an electrical signal and configured to converge light. For detailed description, reference may be made to the related description in Embodiment 1. Details are not described herein again.

In this embodiment, the filter array 902 is similar to the filter array 102 in the previous embodiment, both including at least one filter unit set, and the filter unit set includes filters corresponding to different preset wavelengths. Different from the filter array 102 in Embodiment 1, the filters in the filter unit set of the filter array 902 in this embodiment are arranged in a preset target manner, and when the filters are arranged in the foregoing manner, image acquisition indicators corresponding to the filter unit set are optimal.

In an embodiment, before the target manner is determined, image acquisition indicators corresponding to candidate manners may be respectively determined. An optimal image acquisition indicator is determined based on the image acquisition indicators of all candidate manners. A candidate manner corresponding to the optimal image acquisition indicator is used as the target manner. In an embodiment, the image acquisition indicator includes a plurality of indicator dimensions. Different weight values may be configured for the different indicator dimensions according to different use scenarios. A weighting operation is performed according to indicator values corresponding to a candidate manner in the indicator dimensions and the configured weight value, so that an image acquisition indicator corresponding to the candidate manner can be calculated. If the value of the image acquisition indicator is larger, it indicates that the adaptability to a use scenario is higher, an imaging effect is better, and the recognition accuracy is higher. Based on this, a candidate manner corresponding to an image acquisition indicator with the largest value may be chosen as the target manner.

In an embodiment, the filter unit set includes an m*n filter matrix. That is, in one filter unit set, the filters are arranged in a manner of m rows and n columns, to form one m*n filter matrix. For example, the filters in the filter matrix may be square filters or may be rectangular filters. m and n are both positive integers greater than 1. For example, m may be 2, 3, 4, or the like. Correspondingly, n may also be 2, 3, 4, or the like. The values of m and n may be the same or may be different. Specific values of m and n are not limited herein.

For example, according to the colors of filters included in a filter unit set, the filter unit set (that is, the filter matrix) may be categorized into several types as follows, which are respectively: a GRBG filter, an RGGB filter, a BGGR filter, and a GBRG filter, where G represents a filter that allows the passage of green light, R represents a filter that allows the passage of red light, and B represents a filter that allows the passage of blue light.

A 3*3 filter matrix is used as an example for description. For example, FIG. 10 is a schematic diagram of a filter matrix and a filter array according to an embodiment of this application. Referring to FIG. 10, the filter matrix includes nine filters. As shown in (a) of FIG. 10, the nine filters may be filters corresponding to different preset wavelengths, or certainly may be filters corresponding to fewer than 9 different preset wavelengths. In this case, one filter matrix includes two or more filters corresponding to repetitive preset wavelengths. Preferably, the filter matrix includes different filters corresponding to at least four different preset wavelengths. One filter matrix may include a plurality of filter unit sets, for example, include a*b filter unit sets (that is, a filter array). Therefore, the entire filter array is shown in (b) of FIG. 10. Each column of the filter array includes m*a filters, and each row includes n*b filters. If each filter is associated with one pixel unit, the resolution of the generated multispectral image sensor is (m*a)*(n*b). Similarly, if the filter matrix is a 4*4 filter matrix, the filter matrix may include filters corresponding to sixteen different preset wavelengths, or filters corresponding to fewer than sixteen preset wavelengths, for example, only includes filters corresponding to eight different preset wavelengths. That is, two repetitive filters corresponding to the same preset wavelength are required, to ensure a uniform spatial distribution.

A 3*3 filter matrix with a total of 9 different preset wavelengths (that is, allowing the passage of different specific colors) continues to be used as an example for description. The positions of the filters in the filter matrix are mainly determined based on several aspects as follows. 1) From the perspective of the entire filter array, the specific position of a single color in the 3*3 matrix is not required. Therefore, relative positions between different colors in one filter matrix (that is, the filter unit set) need to be considered. 2) It needs to be considered whether there is a specific requirement for the relative positions of colors in subsequent scenario applications. 3) The recovery effect of a color image (for example, an RGB image) is strongly correlated to the relative positions of colors. Therefore, if a scenario application does not have a specific requirement for the relative positions of colors, the demand of a color image recovery algorithm (which subsequently becomes an RGB recovery algorithm) is mainly considered in the design of the spatial arrangement of filters corresponding to different preset wavelengths in a filter array.

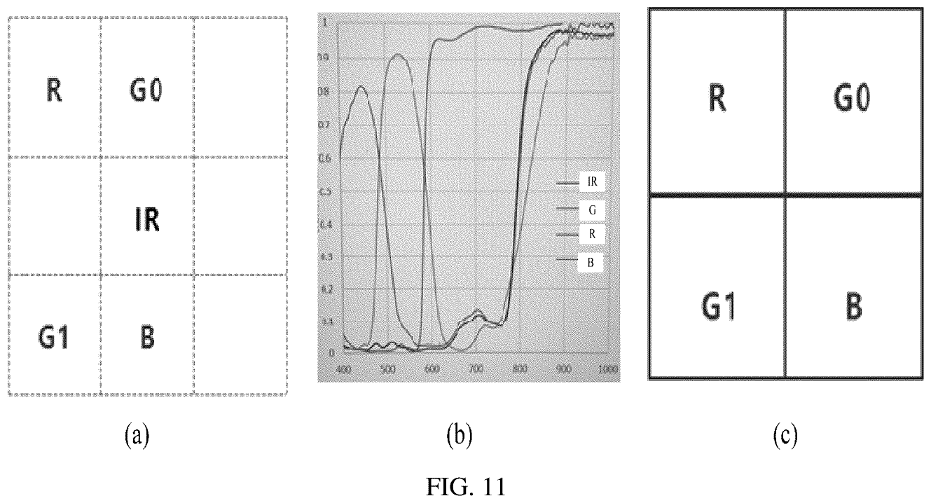

In this embodiment, FIG. 11 is a schematic diagram of an RGB recovery algorithm used in a multispectral image sensor according to an embodiment of this application. Referring to (a) of FIG. 11, a filter matrix in a filter array is an RGGB filter matrix. Therefore, the entire filter matrix includes two filters G1 and G0 that may allow the passage of green light, one filter R that may allow the passage of red light, and one filter B that may allow the passage of blue light, and in addition, further includes a filter IR that may allow the passage of near infrared light. Other wavelengths (that is, colors of light of which the passage may be allowed) that correspond to filters may be selected according to an actual requirement. The performing the RGB recovery algorithm may include the following three steps.
1) A grayscale value of an IR channel is subtracted from the grayscale values of four channels R, G0, G1, and B respectively, that is, R=R−IR, G0=G0−IR, G1=G1−IR, and B=B−IR. The reason of performing the operation in this step is that the filters R, G, and B cannot completely cut off near infrared light, that is, they all have responses to near infrared light. The transmittance curves of the filters are shown in (b) of FIG. 11 below, where the vertical coordinate is an amplitude, and the horizontal coordinate is a wavelength. The responses to near infrared light need to be eliminated to obtain R, G, and B information without interference from other colors. Since a conventional color image sensor carries a filter for filtering near infrared light, the operation in this step is not required. To acquire a variety of spectral information, the multispectral image sensor in this application includes a filter that may allow the passage of near infrared light to acquire spectral data of near infrared light.
2) After the above operation is completed and grayscale values of the four channels R, G0, G1, and B are processed, the entire filter matrix (that is, the filter unit set) may be approximately considered having an arrangement manner the same as that in (c) of FIG. 11.
3) RGB data obtained after the rearrangement is inputted into a corresponding color signal processing model, thereby outputting a color image. At this point, the RGB color recovery is completed.

A part of the resolution in the filter matrix is sacrificed in the foregoing manner, and 5/9 of spatial information is discarded in a sampling process. For a multispectral image sensor with an original resolution output of 3a*3b, an image resolution of an RGB output of the image sensor is 2a*2b. However, in the foregoing manner, the RGB recovery of the multispectral image sensor can be completed by using a universal color signal processing model, so that the universality and efficiency of the color image recovery can be improved. Therefore, after it is determined that the RGB recovery algorithm is applicable, the image acquisition indicators may be determined according to the recovery effects of the RGB recovery algorithm in different arrangement manners, and the target manner of the filters in the filter matrix may be determined based on the image acquisition indicators.

Further, in another embodiment of this application, the image acquisition indicators include an information sampling rate, a distortion distance, a distance parameter with respect to a reference channel, and a spectral similarity calculated based on a transmittance curve. The image acquisition indicators being optimal, such as optimal image acquisition indicators, refers to that when the filters are arranged in the target manner, the information sampling rate is greater than a sampling rate threshold, the distortion distance is less than a distortion threshold, the distance parameter is less than a preset distance threshold, and a spectral similarity between adjacent filters is greater than a preset similarity threshold. The sampling rate threshold is determined based on information sampling rates of all candidate manners. The distance threshold is determined based on distortion distances of all the candidate manners.

In this embodiment, the image acquisition indicators include four types of feature parameters: an information sampling rate, a distortion distance, a distance parameter with respect to a reference channel, and a spectral similarity between different filters. The calculation manners of three of the feature parameters are respectively described below. Detailed description is as follows.

1) Information Sampling Rate

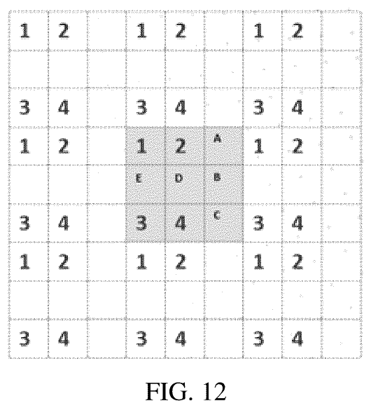

The 3*3 filter matrix continues to be used as an example for description. As described above, during the execution of the RGB recovery algorithm, only four filters provide color information for the RGB recovery algorithm. That is, information of five channels (that is, data acquired by filters at five positions) in the 3*3 array is discarded, and information of only four channels is kept. When the four filters are at different positions in the 3*3 array, the sampling effects on the spatial information of the entire filter matrix are different. Therefore, a sampling effect on the spatial information when the filters of the four colors are at different positions may be indicated by using an information sampling rate. For example, FIG. 12 is a schematic diagram of the arrangement positions of different filters of RGB channels in a filter array according to an embodiment of this application. As shown in FIG. 12, for example, the filter matrix in the filter array is an RGGB matrix. The positions of the four filters (which are respectively filters 1 to 4) in the filter matrix are shown in the figure, so that a corresponding filter array is formed based on the filter matrix. Acquired information corresponding to a pixel A is discarded during the execution of the RGB recovery algorithm. Therefore, if the information of the pixel A needs to be recovered, information of other pixels in neighboring regions of the pixel A is used for supplementation. Among the eight neighboring region pixels of the pixel A, four pixels on the top, bottom, left, and right are closer to the center (that is, the pixel A) than four pixels on the upper left, upper right, lower left, and lower right, and therefore contribute more accurate information. Therefore, an amount of information contributed during the recovery of the information of the pixel A by the pixels in neighboring regions on the top, bottom, left, and right of the pixel A may be recognized as 1, and an amount of information contributed during the recovery of the information of the pixel A by the pixels in neighboring regions on the upper left, upper right, lower left, and lower right may be recognized as 0.707 (that is,

$$\frac{1}{\sqrt{2}} ) .$$

Based on this, when the filter matrix is arranged in the foregoing manner in FIG. 12, among the eight neighboring regions of the pixel A, an RGGB filter is configured respectively in only the four pixels on the upper left, upper right, left, and right. That is, the acquired information of the four pixels are valid. The information of other neighboring region pixels is discarded during the RGB recovery, that is, the information is invalid information. Therefore, an amount of information that can be obtained from the neighboring regions for the pixel A is a total sum of the four neighboring regions. That is, SA=0.707+0.707+1+1=3.414. Similarly, the amounts of information corresponding to pixels B, C, D, and E may be calculated respectively in the foregoing manner. Eventually, a total amount of information obtained for the five discarded pixels in the 3*3 arrangement is calculated as S=SA+SB+SC+SD+SE=16.484. The total amount S of information is used as an information sampling rate of the arrangement manner. S represents a total amount of information that can be provided for a full-resolution image recovery by the filter matrix corresponding to the RGGB filters in the arrangement manner. When the total amount of provided information is larger, the data loss is smaller. Therefore, when the information sampling rate is larger, the effect is better. During the determination of the target manner, a corresponding sampling rate threshold may be configured. If an information sampling rate corresponding to a candidate manner is greater than the sampling rate threshold, comparison of other feature parameters may be performed, to determine whether the candidate manner is the target manner.

Further, the sampling rate threshold may be determined according to information sampling rates corresponding to all candidate manners. For example, an information sampling rate with the second largest value in all the candidate manners may be used as the sampling rate threshold, thereby selecting an information sampling rate with the largest value as the sampling rate threshold.

2) Distortion Distance

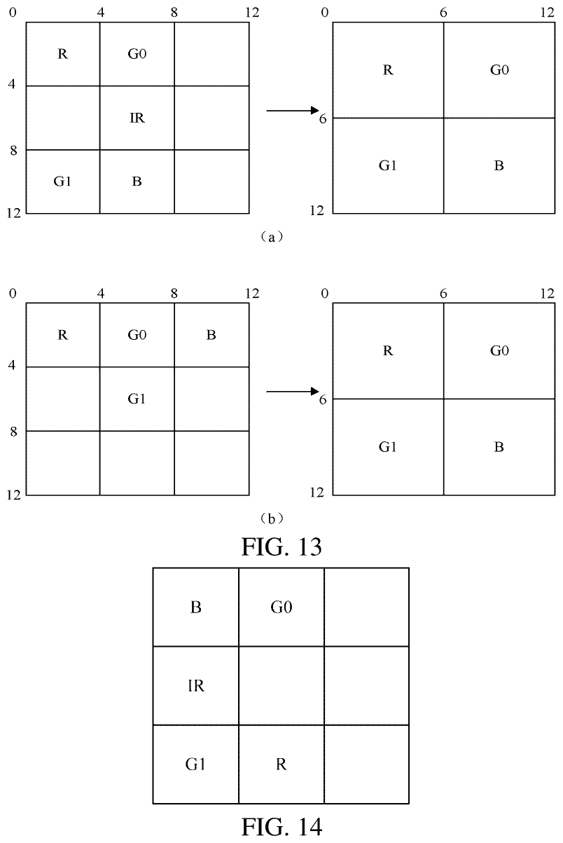

For example, FIG. 13 is a schematic diagram of calculation of a distortion distance according to an embodiment of this application. Referring to FIG. 13, this application provides two arrangement manners of a filter matrix. The first manner is shown in (a) of FIG. 13, and the other manner is shown in (b) of FIG. 13. A 3*3 filter matrix is used as an example for description. A coordinate system is established in a manner in FIG. 13. Certainly, a coordinate system may be established in another manner. The coordinate origin is the upper left corner, and the length and width corresponding to each filter are both 4. In the filter matrix, the center coordinate of a pixel R is (2, 2). After the RGB recovery algorithm is performed (referring to above 1 of the information sampling rate) for the approximate conversion of a matrix, in a matrix after an equivalent approximate RGB recovery, four filters (that is, four filters of RGGB) are used to replace the space occupied by the original nine filters. Therefore, the length and width of each pixel are both changed into 6. In this case, the center coordinate of the pixel R is (3, 3). In the operation of the approximate conversion of a matrix, a distortion amount is introduced for an R channel (that is, a red filter). The distortion amount is \sqrt{(3−2)²+(3−2)²}=\sqrt{2}, that is, 1.414. Similarly, the distortion amounts of the other three channels may be calculated. The distortion distance is equal to a total sum of the distortion distances of the channels. In different 4-channel arrangement designs, when the distortion distance is smaller, the effect is better. As can be seen, for the arrangement in the foregoing manner (a) in FIG. 13, the distortion distance corresponding to the filter matrix is 9.153. In addition, another case needs to be considered in the calculation of the distortion distance. For example, for the arrangement in (b) of FIG. 13, as shown in the right part of the figure, in the original 3*3 array design, a B channel is located on the right of a G0 channel. After the approximate conversion, the B channel is located below the G0 channel. Such an approximate conversion that changes the spatial topological positions of the four channels causes relatively severe adverse impact to the RGB effect. Therefore, in this arrangement design, the distortion amount of the G0 channel is multiplied by a penalty factor during the calculation of the total distortion amount. For example, the penalty factor is 2. Similarly, the distortion amount of the B channel also needs to be multiplied by the penalty factor of 2. Therefore, after the penalty factor is calculated, for the arrangement in the foregoing manner in (b) of FIG. 13, a distortion corresponding to the filter matrix is 27.2039. As can be seen, to choose a target manner, a candidate manner with a relatively small distortion distance should be chosen as the target manner. Therefore, if a distortion distance corresponding to a candidate manner is less than the distortion threshold, comparison of other feature parameters may be performed to determine whether the candidate manner is a target manner.

Further, the distortion threshold may be determined according to the distortion distances corresponding to all candidate manners. For example, a distortion distance with the second smallest value in the distortion distances of all the candidate manners may be used as the distortion threshold, thereby selecting a distortion distance with the smallest value as the distortion threshold.

3) Distance Parameter with Respect to a Reference Channel

As described above, during the execution of the RGB recovery algorithm, the grayscale value of the near infrared light IR channel first needs to be respectively subtracted from the grayscale values of four channels. Therefore, the IR channel may be used as a reference channel. Certainly, in other application scenarios, if a channel corresponding to a filter with another wave band is used as the reference channel, the IR channel may be replaced with a channel of the corresponding wave band. During the execution of the RGB recovery algorithm, IR components in the grayscale values of the four channels are the same as the grayscale value of the IR channel. Therefore, in the determination of the arrangement manner of the filter matrix, the positions of the filters corresponding to the four channels (that is, the RGGB channels) in the filter matrix need to be as close to the position of the filter corresponding to the IR channel as possible, and the four channels should have distances as close to the IR channel as possible. For this, the distances between the filters corresponding to the four channels and the IR filter and the fluctuation values of the distances are defined. For example, FIG. 14 shows an arrangement manner of filters in a filter matrix according to another embodiment of this application. Referring to FIG. 13, the distance between the B channel (that is, the filter that may allow the passage of blue light) and the IR channel is 1. The G0 channel is located on the upper left of IR channel. Therefore, the distance between the G0 channel and the IR channel is 1.414 (that is, \sqrt{2}). The distances may be determined for the rest in the foregoing manner. Therefore, in the filter matrix obtained in the arrangement manner, a sum of the distances between the four channels and the IR channel is 1+1+1.414+1.414=4.828. An IR distance fluctuation is a standard deviation of the distances of the four channels and the IR channel, which is 0.239. In different candidate manners of the filter matrix, the effect is better when the sum of the distances and the IR distance fluctuation are smaller.

4) Spectral Similarity Calculated Based on a Transmittance Curve

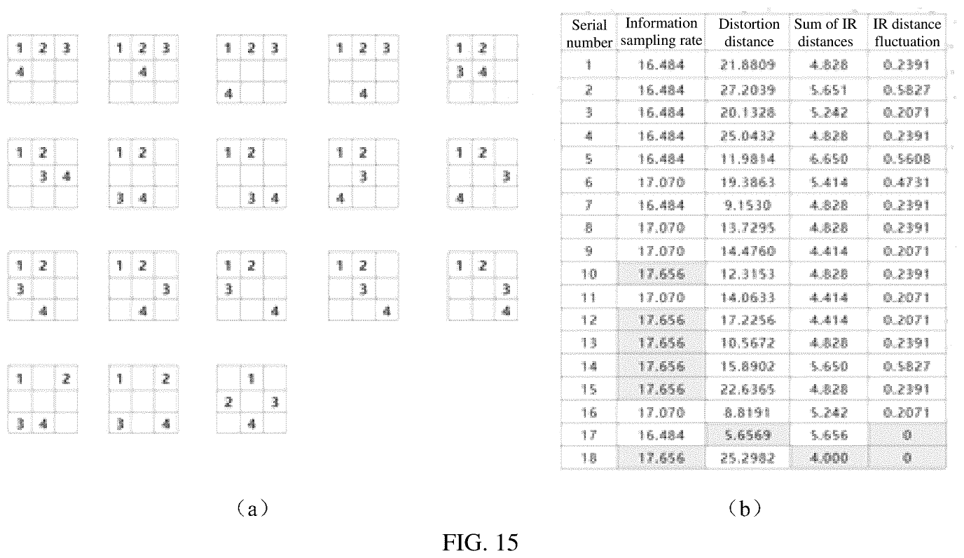

After the information sampling rate, the distortion distance, and the distance parameter (that is, the sum of distances and the IR distance fluctuation) corresponding to the candidate manners are calculated, all the candidate manners may be quantitatively evaluated. For example, FIG. 15 shows a parameter table of the three parameters in all candidate manners according to diagrams of this application. As shown in (a) of FIG. 15, sequence numbers 1 to 18 are provided from left to right and from to bottom. For specific parameters, reference may be made to the table in (a) of FIG. 15. Therefore, according to the comparison of the information sampling rate, the distortion distance, and the distance parameter with respect to the reference channel (that is, the sum of distances of the IR channels and the IR distance fluctuation) in the candidate manners, the sampling rate threshold, the distortion threshold, and the distance threshold may be determined, and an optimal arrangement manner of the four channels and the reference channel (that is, the IR channel) may be determined as shown in (b) of FIG. 15.

After the positions corresponding to the five channels are determined, filters that need to be placed at the remaining four positions in the matrix may be determined. Because different colors should be distributed as uniformly as possible in space, it should be avoided that filters with close colors are located in an excessively close approximate in the 3*3 filter matrix, that is, close colors should be kept from being adjacent as much as possible. The foregoing figure is used as an example for description. Transmittance curves corresponding to the remaining four filters that each has a to-be-determined position are determined, and any filter with to-be-determined position is placed in a vacant position. A spectral similarity between a transmittance curve of the filter with to-be-determined position and an adjacent transmittance curve of a filter with a determined position is calculated. A similarity between the two transmittance curves may be determined based on a similarity measurement indicator for a spectral curve used in the field of spectral measurement. For example, a similarity measurement indicator such as a Euclidean distance, a spectral corner, or a related coefficient between two transmittance curves may be used. This is not limited herein. A position with the smallest similarity is determined from a plurality of vacant positions as the position of the filter with a to-be-determined position. The position of the filter with a to-be-determined position in the filter matrix is obtained in the foregoing manner, so that a transmittance curve corresponding to each filter has a preset weighting correlation with a transmittance curve of a filter in a neighboring region of the filter. The foregoing steps are sequentially performed for all the filters with a to-be-determined position, so that a corresponding target manner during the arrangement of the filters in the filter matrix may be determined from all the candidate manners.

In an embodiment, based on the calculation manners of the four feature parameters, a terminal device may perform traversal to calculate the parameter values corresponding to the four feature parameters of all candidate manners of the filter matrix, and calculate the image acquisition indicators corresponding to the candidate manners based on the parameter values corresponding to the feature parameters, so that an optimal image acquisition indicator can be chosen, and a candidate manner corresponding to the optimal image acquisition indicator is used as the target manner.

In an embodiment, the multispectral image sensor provided in this embodiment may be integrated in an imaging module. In this case, the imaging module includes the multispectral image sensor, a lens, and a circuit board. At least one multispectral image sensor and at least one lens are arranged on the circuit board. The lens is arranged on the multispectral image sensor, to make incident light pass through the lens to irradiate the multispectral image sensor.

In the embodiments of this application, the image acquisition indicators are determined in a plurality of feature dimensions. The feature dimensions include an information acquisition degree, a distortion degree, a correlation between filters, and a fluctuation range from a center point, to quantitatively assess an acquisition effect of a filter matrix in a plurality of aspects, so that an optimal target arrangement manner can be accurately and effectively determined, thereby improving the acquisition precision of a multispectral image sensor and the adaptability between application scenarios.

The foregoing embodiments are merely for describing the technical solutions of this application, but not for limiting this application. This application is described in detail with reference to the foregoing embodiments, and a person of ordinary skill in the art may make modifications to the technical solutions described in the foregoing embodiments or make equivalent replacements to some technical features thereof, without departing from the spirit and scope of the technical solutions of the embodiments of this application, which are included in the protection scope of this application.

What is claimed is:

1. An image sensor, comprising a microlens array, a filter array, and a photosensitive chip sequentially arranged along a direction of incident light, wherein
the photosensitive chip comprises a plurality of pixel units;
the filter array comprises at least one filter unit set, each of the at least one filter unit set comprises a plurality of filters corresponding to different wavelengths, and each of the plurality of filters is configured for a corresponding wavelength of the incident light to pass; and
the microlens array comprises at least one microlens unit, and the at least one microlens unit is configured to converge the incident light, and focus the converged incident light on the photosensitive chip after passing through the filter array.

2. The image sensor according to claim 1, wherein each of the at least one filter unit set comprises a broadband filter matrix, and the broadband filter matrix is configured for light in a visible light band and an infrared band in the incident light to pass.

3. The image sensor according to claim 1, wherein the filters corresponding to the different wavelengths in the filter array are arranged in a two-dimensional plane.

4. The image sensor according to claim 1, wherein
the photosensitive chip further comprises a plurality of photodiodes and a signal processing module, and each of the plurality of pixel units comprises at least one photodiode;
the photodiodes are electrically connected to the signal processing module;
each of the photodiodes is configured to convert an optical signal into an electrical signal; and
the signal processing module is configured to process the electrical signals outputted by the plurality of pixel units to obtain a light sensing result.

5. The image sensor according to claim 1, wherein one filter in the at least one filter unit set covers one or more of the plurality of pixel units.

6. The image sensor according to claim 1, wherein the at least one filter unit set is a 3*3 filter matrix.

7. The image sensor according to claim 1, further comprising a base, wherein the photosensitive chip, the filter array, and the microlens array are sequentially arranged on the base.

8. The image sensor according to claim 1, wherein each of the at least one microlens unit is arranged on each of the at least one filter unit set.

9. An imaging device, comprising at least one image sensor, at least one lens, and a circuit board, wherein
the at least one image sensor comprises a microlens array, a filter array, and a photosensitive chip sequentially arranged along a direction of incident light, wherein
the photosensitive chip comprises a plurality of pixel units;
the filter array comprises at least one filter unit set, each of the at least one filter unit set comprises a plurality of filters corresponding to different wavelengths, and each of the plurality of filters is configured for a corresponding wavelength of the incident light to pass; and
the microlens array comprises at least one microlens unit, and the at least one microlens unit is configured to converge the incident light, and focus the converged incident light on the photosensitive chip after passing through the filter array;
the at least one image sensor and the at least one lens are arranged on the circuit board; and
the at least one lens is arranged on the at least one image sensor, to irradiate the incident light on the at least one image sensor after passing through the at least one lens.

10. The imaging device according to claim 9, wherein
the at least one lens comprises an imaging lens and a pedestal;
the imaging lens is arranged on the pedestal; and
the at least one image sensor is connected to the pedestal and is arranged on the circuit board.

11. The device according to claim 9, wherein each of the at least one filter unit set comprises a broadband filter matrix, and the broadband filter matrix is configured for light in a visible light band and an infrared band in the incident light to pass.

12. The device according to claim 9, wherein the filters corresponding to the different wavelengths in the filter array are arranged in a two-dimensional plane.

13. The device according to claim 9, wherein
the photosensitive chip further comprises a plurality of photodiodes and a signal processing module, and each of the plurality of pixel units comprises at least one photodiode;
the photodiodes are electrically connected to the signal processing module;
each of the photodiodes is configured to convert an optical signal into an electrical signal; and
the signal processing module is configured to process the electrical signals outputted by the plurality of pixel units to obtain a light sensing result.

14. The device according to claim 9, wherein one filter in the at least one filter unit set covers one or more of the plurality of pixel units.

15. The device according to claim 9, wherein the at least one filter unit set is a 3*3 filter matrix.

16. The device according to claim 9, wherein the at least one image sensor comprising a base, and the photosensitive chip, the filter array, and the microlens array are sequentially arranged on the base.

17. The device according to claim 9, wherein each of the at least one microlens unit is arranged on each of the at least one filter unit set.
